(19) United States
(12) Patent Application Publication
(10) Pub. No.: US 2008/0049402 A1
(43) Pub. Date: Feb. 28, 2008

(54) PRINTED CIRCUIT BOARD HAVING SUPPORTING PATTERNS

(75) Inventors: Jun-Soo HAN, Chungcheongnam-do (KR); Gil-Beag KIM, Chungcheongnam-do (KR); Yong-Jin JUNG, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/775,148

(22) Filed: Jul. 9, 2007

(30) Foreign Application Priority Data
Jul. 13, 2006 (KR) 2006-0065872

(51) Int. Cl. H05K 1/18

(52) U.S. Cl. 361/748

(57) ABSTRACT

A printed circuit board having supporting patterns is provided. The printed circuit board includes a base substrate having a circuit region and peripheral regions. The circuit region includes a plurality of unit cells arranged in a matrix, and the peripheral regions are located around the circuit region. Wires are located on the circuit region. First supporting bars are located on the peripheral regions and extend across the peripheral regions, and a plurality of supporting ribs traverse the first supporting bars.

### CROSS-REFERENCE TO RELATED PATENT APPLICATION

This application claims the benefit of priority to Korean Patent Application No. 10-2006-0065872, filed on Jul. 13, 2006, the disclosure of which is incorporated herein in its entirety by reference.

### BACKGROUND

1. Field of Invention

Embodiments of the present invention relate generally to printed circuit boards and, more particularly, to a printed circuit board having supporting patterns adapted to protect against warping.

2. Description of the Related Art

As semiconductor products become further minimized, semiconductor packages must generally be lighter, thinner and smaller and must also achieve a higher degree of integration of semiconductor chips. In light of these requirements, solder ball packages using solder balls as mounting elements (e.g., ball grid array (BGA) packages) have been developed.

Conventional BGA packages are fabricated by locating a chip on one surface of a printed circuit board and arranging solder balls on the other surface of the printed circuit board. During fabrication of the package, warping of the printed circuit board caused due to a temperature variation may occur.

FIGS. 1A through 1C illustrate various cases in which warping of a printed circuit board 10 can occur.

Referring to FIG. 1A, a bottom surface of the printed circuit board 10 expands more than a top surface thereof. As a result, both ends of the printed circuit board 10 are bent upward. Referring to FIG. 1B, the top surface of the printed circuit board 10 expands more than bottom surface thereof. As a result, both ends of the printed circuit board 10 are bent downward. Referring to FIG. 1C, the printed circuit board 10 partially expands and partially contracts. As a result, the center portion and both ends of the printed circuit board 10 are bent upward.

Because of such warping, the printed circuit board 10 cannot be smoothly transferred into a processing apparatus during semiconductor assembling. Moreover, the printed circuit board 10 cannot be seated within the processing apparatus in a substantially planar manner. As a result, various assembly operations can be made more difficult or impossible. Also, when a package is mounted on a module substrate, reliability of connections between the solder balls and the ball pads on the module substrate, i.e., mounting reliability, may be degraded.

### SUMMARY

Exemplary embodiments generally described herein may help to reduce or substantially prevent warping of a printed circuit board.

One embodiment exemplarily described herein may be characterized as a printed circuit board that includes a base substrate; a first supporting bar formed on the base substrate; and a plurality of first supporting ribs. The base substrate may include a circuit region and peripheral regions located around the circuit region. The first supporting bar may be within one of the peripheral regions and extend along a length of the one of the peripheral regions. The plurality of first supporting ribs may be within the one of the peripheral regions and at least one of the plurality of first supporting ribs may traverse the first supporting bar.

Another embodiment exemplarily described herein may be characterized as a printed circuit board that includes a base substrate having a top surface and a bottom surface opposite the top surface; a first supporting bar disposed on the top surface; a plurality of first supporting ribs disposed on the top surface; a second supporting bar disposed on the bottom surface; a plurality of second supporting ribs disposed on the bottom surface; and an auxiliary supporting bar disposed on the base substrate. The base substrate may include a circuit region and peripheral regions located around a periphery of the circuit region. The circuit region may include an upper part, a lower part opposite the upper part, a left part between the upper and lower parts and a right part opposite the left part. The peripheral regions may include an upper peripheral region adjacent to the upper part, a lower peripheral region adjacent to the lower part, a left peripheral region adjacent to the left part and a right peripheral region adjacent to the right part. A length of the upper peripheral region along the upper part may be greater than a length of at least one of the left and right peripheral regions along the left and right parts. The first supporting bar may be disposed in the upper peripheral region and extend along the length of the upper peripheral region. The second supporting bar may be disposed in the upper peripheral region. A location of the second supporting bar on the bottom surface in the upper peripheral region may substantially correspond to a location of the first supporting bar on the top surface in the upper peripheral region. The plurality of first supporting ribs may be disposed within the upper peripheral region and at least one of the plurality of first supporting ribs may traverse the first supporting bar. The plurality of second supporting ribs may be disposed within the upper peripheral region and at least one of the plurality of second supporting ribs may traverse the second supporting bar. The auxiliary supporting bar may be disposed in at least one of the left and right peripheral regions and the auxiliary supporting bar may be substantially parallel to at least one of the first and second supporting bars.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1C illustrate various cases in which warping of a printed circuit board can occur;

FIGS. 2A and 2B are plan views illustrating a top surface and a bottom surface, respectively, of a printed circuit board according to one embodiment;

FIGS. 3A and 3B are enlarged plan views of regions U1 and U2, respectively, shown in FIGS. 2A and 2B, respectively, which illustrate top and bottom surfaces of a unit cell;

FIGS. 4A and 4B are plan views illustrating supporting patterns disposed on top and bottom surfaces of the printed circuit board illustrated in FIGS. 2A and 2B, respectively;

FIG. 5 is a cross-sectional view taken along a line V-V′ as shown in FIG. 3A;

FIG. 6 is a cross-sectional view taken along a line VI-VI′ as shown in FIG. 2A;

FIG. 7 is a cross-sectional view illustrating a method of fabricating a semiconductor package using a printed circuit board according to one embodiment;

FIGS. 8A and 8B are plan views illustrating a top surface and a bottom surface, respectively, of a printed circuit board according to another embodiment;

FIG. 9 is a sectional view taken along a line IX-IX′ as shown in FIG. 8A;

FIG. 10 is a plan view illustrating supporting patterns of the printed circuit board of a comparative example; and

FIG. 11 is a graph plotting the warping of the printed circuit board illustrated in FIGS. 2A and 2B and that of the comparative example.

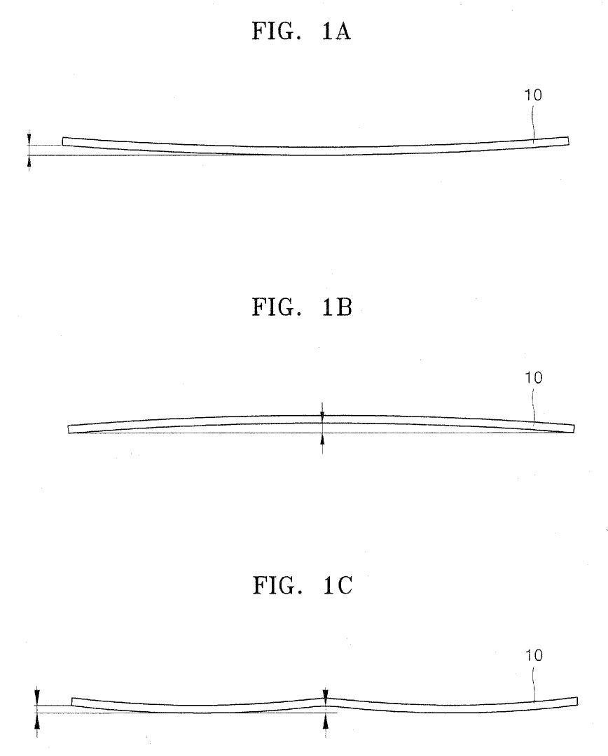

### DETAILED DESCRIPTION

Embodiments of the present invention will now be described more fully with reference to the accompanying drawings. These embodiments may, however, be realized in many different forms and should not be construed as being limited to the embodiments set forth herein. Rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will not be repeated.

### First Embodiment

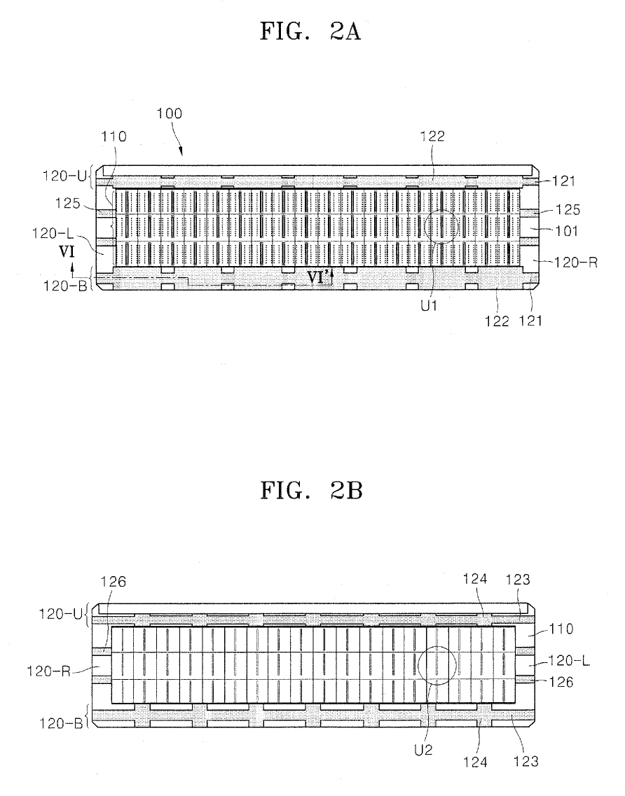

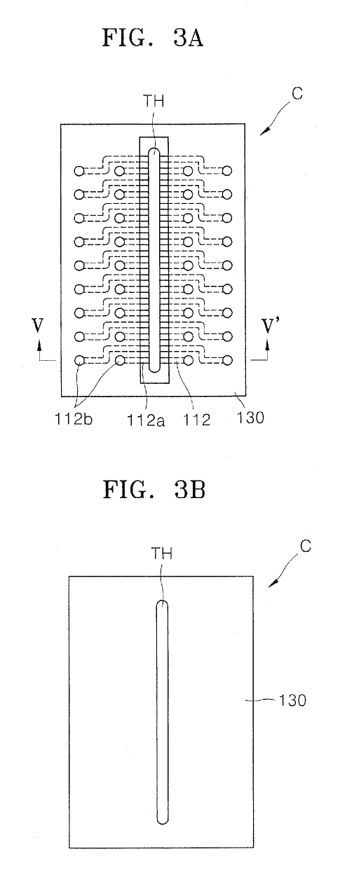

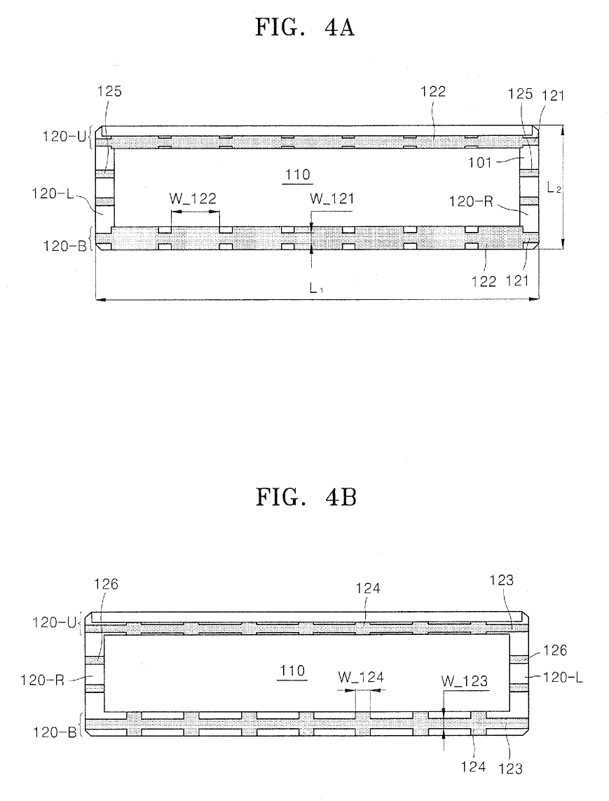

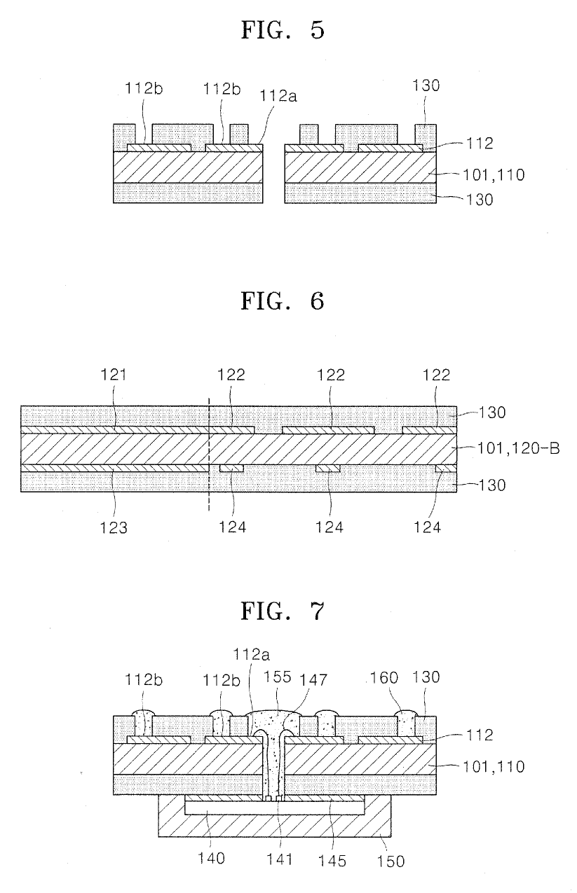

FIGS. 2A and 2B are plan views illustrating a top surface and a bottom surface, respectively, of a printed circuit board according to one embodiment. FIGS. 3A and 3B are enlarged plan views of regions U1 and U2, respectively, shown in FIGS. 2A and 2B, respectively, which illustrate top and bottom surfaces of a unit cell. FIGS. 4A and 4B are plan views illustrating supporting patterns disposed on top and bottom surfaces of the printed circuit board illustrated in FIGS. 2A and 2B, respectively. FIG. 5 is a cross-sectional view taken along a line V-V′ as shown in FIG. 3A. FIG. 6 is a cross-sectional view taken along a line VI-VI′ as shown in FIG. 2A.

Referring to FIGS. 2A and 2B, a printed circuit board 100 may include a base substrate 101. The base substrate 101 may include a circuit region 110. The printed circuit board 100 may also include an upper peripheral region 120-U, a lower peripheral region 120-B, a left peripheral region 120-L and a right peripheral region 120-R disposed around the circuit region 110. The circuit region 110 may also include a plurality of unit cells C arranged in a matrix. In one embodiment, each unit cell C is a unit printed circuit board may be subsequently processed into a single semiconductor package. In the embodiment illustrated in FIGS. 2A and 2B, a unit cell C is located within regions U1 and U2.

Referring to FIGS. 3A, 3B and 5, each unit cell C may include wires 112 disposed on a top surface of the circuit region 110 of the base substrate 101. In some embodiments, the base substrate 101 may include a thru-hole TH penetrating therethrough and the wires 112 may be disposed adjacent to the thru-hole TH. A solder resist 130 may be formed on the wires 112. Openings may be defined through the solder resist 130 to expose portions of the wires 112. As a result, a portion of each wire 112 may be exposed by an opening in a wire bonding region 112a and another portion of each wire 112 may be exposed by another opening in a ball pad region 112b.

In some embodiments, no wires are provided on the bottom surface of the circuit region 110 but the solder resist 130 may nevertheless cover the bottom surface of the circuit region 110.

Referring to FIGS. 4A, 4B and 6, the upper peripheral region 120-U, the lower peripheral region 120-B, the left peripheral region 120-L and the right peripheral region 120-R correspond to upper-, lower-, left- and right-illustrated parts, respectively, of the circuit region 110. A first supporting bar 121 and a plurality of first supporting ribs 122 are located on a top surface of the base substrate 101 in at least one of the peripheral regions 120-U, 120-B, 120-L and 120-R. In some embodiments, the first supporting bar 121 extends along one peripheral region and the plurality of first supporting ribs 122 project from the first supporting bar 121.

The first supporting ribs 122 traverse the first supporting bars 121. Therefore, the first supporting ribs 122 may vertically traverse at least one of the peripheral regions 120-U, 120-B, 120-L and 120-R. As described above, one relatively thick first supporting bar 121 is disposed within one peripheral region and the plurality of first supporting ribs 122 traversing the first supporting bar 121 are disposed to support the base substrate 101. By doing so, stiffness of the base substrate 101, i.e., the printed circuit board 100, can be effectively increased. Therefore, the warping of the printed circuit board 100 can be decreased. A distance between each of the first supporting ribs 122 may be substantially the same.

In one embodiment, the first supporting bars 121 and the first supporting ribs 122 may be formed on top surfaces of the base substrate 101 in the upper peripheral region 120-U and the lower peripheral region 120-B. In such an embodiment, a length L1 of each of the upper peripheral region 120-U and the lower peripheral region 120-B may be greater than a length L2 of each of the left peripheral region 120-L and the right peripheral region 120-R. Therefore, the first supporting bars 121 and the first supporting ribs 122 are each disposed on the base substrate 101 in the upper peripheral region 120-U and the lower peripheral region 120-B corresponding to the longer axis of the printed circuit board 100 to effectively prevent warping that can occur more frequently in the longer axis.

In one embodiment, the first supporting bars 121, the first supporting ribs 122 and the wires 112 formed on the circuit region 110 comprise substantially the same material. For example, the first supporting bars 121, the first supporting ribs 122 and the wires 112 may comprise, or be composed of, copper. The solder resist 130 may be formed on the first supporting bar 121 and the first supporting ribs 122.

In one embodiment, at least one second supporting bar 123 may be formed on the bottom surface of the base substrate 101 in at least one of the peripheral regions 120-U, 120-B, 120-L and 120-R. In one embodiment, the second supporting bar 123 may be formed on the bottom surface of the base substrate 101 in the same peripheral region within which a first supporting bar 121 is formed. In another embodiment, the location of the second supporting bar 123 on the bottom surface of the base substrate 101 in a peripheral region may substantially correspond to the location of the first supporting bar 121 on the top surface of the base substrate 101 in the same peripheral region. For example, at least a part of the second supporting bar 123 may be located on a portion of the bottom surface of the base substrate 101 that is opposite to a portion of the top surface of the base substrate 101 on which at least a part of the first supporting bar 121 is located, along a direction substantially perpendicular to the top and bottom surfaces of the base substrate 101. In some embodiments, substantially all of the second supporting bar 123 is located on a portion of the bottom surface of the base substrate 101 that is opposite to a portion of the top surface of the base substrate 101 on which substantially all of the first supporting bar 121 is located, along a direction substantially perpendicular to the top and bottom surfaces of the base substrate 101. Accordingly, in the illustrated embodiments, second supporting bars 123 may be formed on the bottom surfaces of the base substrate 101 in the upper and lower peripheral regions 120-U and 120-B at locations that substantially correspond with the first supporting bars 121. Due to the presence of the first supporting bars 121 and the second supporting bars 123, the stiffness of the printed circuit board 100 may be further increased, thereby more effectively decreasing warping of the printed circuit board 100. In one embodiment, a width of the first supporting bar 121 in one peripheral region (e.g., w_121) and a width of the second supporting bar 123 in the same peripheral region (e.g., w_123) may be substantially the same. As generally illustrated, the width of a first or second supporting bar 121 or 123 in one peripheral region may be different from a width of a corresponding first or second supporting bar 121 or 123 in a different peripheral region.

In one embodiment, a plurality of second supporting ribs 124 traversing the second supporting bars 123 may be formed on bottom surfaces of the base substrate 101 in the upper peripheral region 120-U and the lower peripheral region 120-B. A distance between each of the second supporting ribs 124 may be substantially the same.

In some embodiments, a width w_124 of the second supporting ribs 124 and a width w_122 of the first supporting ribs 122 may be different. In one embodiment, the width w_124 of the second supporting ribs 124 and the width w_122 of the first supporting ribs 122 may be differently set according to a typical warping direction of the printed circuit board not having the first and second supporting bars 121 and 123 and the first and second supporting ribs 122 and 124. For example, if the top surface of the printed circuit board 100 expands more than the bottom surface to make the center bulge upward and the ends thereof bend downward, then the width w_122 of the first supporting ribs 122 located on the upper surface of the base substrate 101 can be set to be greater than the width w_124 of the second supporting ribs 124 located on the bottom surface of the base substrate 101. However, if the bottom surface of the printed circuit board 100 expands more than the top surface to make the center bulge downward and the ends thereof bend upward, then the width w_124 of the second supporting ribs 124 located on the bottom surface of the base substrate 101 can be greater than the width w_122 of the first supporting ribs 122 located on the top surface of the base substrate 101.

First auxiliary supporting bars 125, disposed substantially in parallel with the first supporting bars 121, may be disposed on the top surface of the base substrate 101 in the left peripheral region 120-L and the right peripheral region 120-R. Second auxiliary supporting bars 126, disposed in parallel with the second supporting bars 123, may be disposed on the bottom surface of the base substrate 101 in the left peripheral region 120-L and the right peripheral region 120-R. In one embodiment, the location of a first auxiliary supporting bar 125 on the top surface of the base substrate 101 may substantially correspond to the location of a second auxiliary supporting bar 126 on the bottom surface of the base substrate 101.

FIG. 7 is a cross-sectional view illustrating a method of fabricating a semiconductor package using a printed circuit board according to one embodiment, which is defined to a unit cell.

Referring to FIG. 7, a semiconductor chip 140 may be adhered to a bottom surface of the printed circuit board 100 using an insulating adhesive 145. In the illustrated embodiment, a single semiconductor chip 140 may be adhered to a corresponding single unit cell C of the printed circuit board 100. Then, a terminal pad 141 of the semiconductor chip 140, exposed by a thru-hole TH of the unit cell C, and a wire bonding region 112a of the unit cell C may be electrically connected by using a conductive wire 147. An encapsulation layer 155 may be formed on the connection portion of the conductive wire 147. Thereafter, the semiconductor chip 140 may be molded using a molding material 150. Subsequently, a plurality of solder balls 160 may be arranged on a top surface of the printed circuit board 100. A thermal treatment may be performed to electrically connect the solder balls 160 to ball pad regions 112b.

While performing such processing, the printed circuit board is heated and/or cooled. Conventional printed circuit boards would become warped when subjected to such temperature increases and/or decreases. However, any or all of the aforementioned supporting bars and supporting ribs described above increase the stiffness of the printed circuit board 100 to decrease the degree to which the printed circuit board 100 warps.

Thereafter, the printed circuit board 100 is separated (e.g., by sawing), and the unit cells C mounted with the semiconductor chips 140 and the solder balls 160 are separated from each other. When the printed circuit board 100 is sawn, the peripheral regions 120-U, 120-B, 120-L and 120-R are removed.

### Second Embodiment

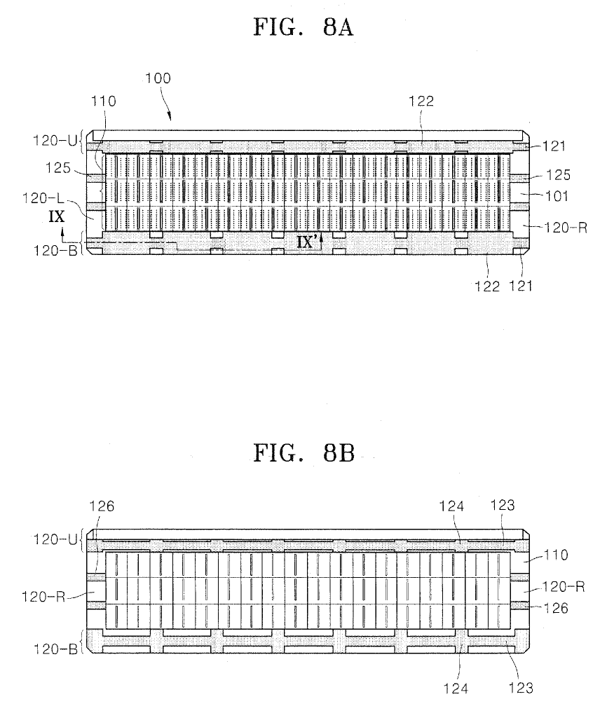

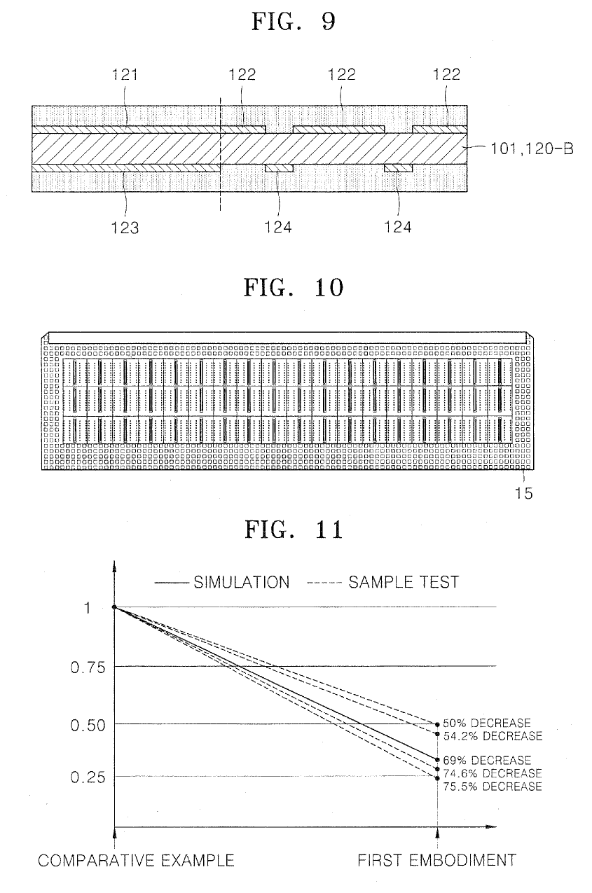

FIGS. 8A and 8B are plan views illustrating a top surface and a bottom surface, respectively, of a printed circuit board according to a second embodiment. FIG. 9 is a sectional view taken along a line IX-IX′ as shown in FIG. 8A. The printed circuit board according to the second embodiment is similar to that described above with reference to the first embodiment except for the following description.

Referring to FIGS. 8A, 8B and 9, first supporting bars 121 and a plurality of supporting ribs 122 are located on the top surface of the base substrate 101 within, for example, the upper peripheral region 120-U and the lower peripheral region 120-B. Further, the first supporting bars 121 extend along the peripheral regions 120-U and 120-B and a plurality of supporting ribs 122 project from the first supporting bars 121.

Second supporting bars 123 and a plurality of second supporting ribs 124 are disposed on the bottom surface of base substrate 101 within the upper peripheral region 120-U and the lower peripheral region 120-B. The location of the second supporting bars 123 on the bottom surface of the base substrate 101 substantially corresponds with the location of the first supporting bars 121 on the top surface of the base substrate 101. The plurality of second supporting ribs 124 traverse the second supporting bars 123. The locations of the second supporting ribs 124 on the bottom surface of the base substrate 101 substantially correspond to a location of a region between the first supporting ribs 122 on the top surface of the base substrate 101. Therefore, when the first supporting ribs 122 are located on the top surface of the base substrate 101 within the peripheral regions, the second supporting ribs 124 are not disposed at locations on the bottom surface of the base substrate 101 within the peripheral regions that substantially correspond to locations of the first supporting ribs 122. Conversely, the second supporting ribs 124 are disposed at locations on the bottom surface of the base substrate 101 in the peripheral regions that substantially correspond to a location where the first supporting ribs 122 are not disposed on the top surface of the base substrate 101 in the peripheral regions. Accordingly, when the printed circuit board 100 is heated or cooled, a thermal deformation of the supporting ribs 122 and 124 itself can be counteracted. Thus, the warping of the printed circuit board 100 can be more effectively prevented.

Hereinafter, the warping improvement of the printed circuit board according to the first embodiment will be described when compared with the warping of the printed circuit board of a comparative example.

FIG. 10 is a plan view illustrating the supporting patterns of the printed circuit board of a comparative example.

Referring to FIG. 10, block-type supporting patterns 15 are located on the top surface of the printed circuit board within all peripheral regions located on the upper and lower parts and the right and left parts of the printed circuit board. More specifically, copper patterns 15 shaped as a rectangle are arranged in matrix. Although not illustrated, block-type supporting patterns, identical to those on the top surface, are also located within peripheral regions of the bottom surface of the printed circuit board.

FIG. 11 is a graph plotting the warping of the printed circuit board illustrated in FIGS. 2A and 2B and that of the comparative example.

Referring to FIG. 11, when the warping of the printed circuit board by the comparative example is considered as 1, the warping according to the first embodiment is 0.25 to 0.5. Thus, it can be noted that the warping is decreased by 50% to 75.5% as compared with the printed circuit board by the comparative example.

According to the embodiments described above, a supporting bar may be disposed on peripheral region by extending along the peripheral region and a plurality of supporting ribs traversing the supporting bar may be formed to support a base substrate. As a result, the stiffness of the base substrate, e.g., a printed circuit board, can be effectively increased. Therefore, warping of the printed circuit board can be effectively decreased.

While embodiments of the present invention have been particularly shown and described above, it will be understood by those of ordinary skill in the art that various changes in form and details may be made therein without departing from the spirit and scope of the present invention as defined by the following claims.

What is claimed is:

1. A printed circuit board comprising:
a base substrate including a circuit region and peripheral regions located around the circuit region;
a first supporting bar formed on the base substrate within one of the peripheral regions, the first supporting bar extending along a length of the one of the peripheral regions; and
a plurality of first supporting ribs within the one of the peripheral regions, wherein at least one of the plurality of first supporting ribs traverses the first supporting bar.

2. The printed circuit board of claim 1, wherein the base substrate includes a top surface and a bottom surface opposite the top surface and wherein the first supporting bar and the plurality of first supporting ribs are formed on the top surface, the printed circuit board further comprising:
a second supporting bar formed on the bottom surface within the one of the peripheral regions.

3. The printed circuit board of claim 2, wherein a location of the second supporting bar on the bottom surface substantially corresponds to a location of the first supporting bar on the top surface.

4. The printed circuit board of claim 2, further comprising a plurality of second supporting ribs on the bottom surface within the one of the peripheral regions, wherein at least one of the plurality of second supporting ribs traverses the second supporting bar.

5. The printed circuit board of claim 4, wherein a width of at least one of the plurality of first supporting ribs is different from a width of at least one of the plurality of second supporting ribs.

6. The printed circuit board of claim 4, wherein a location of at least one of the plurality of second supporting ribs on the bottom surface substantially corresponds to a location of a region between adjacent ones of the plurality of first supporting ribs on the top surface.

7. The printed circuit board of claim 1, wherein:
the circuit region comprises:
an upper part;
a lower part opposite the upper part;
a left part between the upper and lower parts; and
a right part opposite the left part;
the peripheral regions comprise:
an upper peripheral region adjacent to the upper part;
a lower peripheral region adjacent to the lower part;
a left peripheral region adjacent to the left part; and
a right peripheral region adjacent to the right part;
a length of the upper peripheral region is greater than a length of at least one of the left and right peripheral regions along the left and right parts; and
the first supporting bar is formed on the base substrate in the upper peripheral region.

8. The printed circuit board of claim 7, further comprising a plurality of first supporting bars, wherein one of the plurality of first supporting bars is formed on the base substrate in the lower peripheral region.

9. The printed circuit board of claim 8, wherein a length of the lower peripheral region along the lower part is greater than the length of at least one of the left and right peripheral regions along the left and right parts.

10. The printed circuit board of claim 7, wherein the base substrate includes a top surface and a bottom surface opposite the top surface and wherein the first supporting bar and the plurality of first supporting ribs are formed on the top surface, the printed circuit board further comprising:
a second supporting bar formed on the bottom surface in the upper peripheral region.

11. The printed circuit board of claim 10, wherein a location of the second supporting bar on the bottom surface substantially corresponds to a location of the first supporting bar on the top surface.

12. The printed circuit board of claim 10, further comprising a plurality of second supporting ribs on the bottom surface within the upper peripheral region, wherein at least one of the plurality of second supporting ribs traverses the second supporting bar.

13. The printed circuit board of claim 12, wherein a width of at least one of the plurality of first supporting ribs is different from a width of at least one of the plurality of second supporting ribs.

14. The printed circuit board of claim 12, wherein a location of at least one of the plurality of second supporting ribs on the bottom surface substantially corresponds to a location of a region between adjacent ones of the plurality of first supporting ribs on the top surface.

15. The printed circuit board of claim 7, further comprising an auxiliary supporting bar formed on the base substrate in at least one of the left and right peripheral regions, wherein the auxiliary supporting bar is substantially parallel to the first supporting bar.

16. The printed circuit board of claim 1, further comprising:
a wire formed on the circuit region; and
a solder resist formed on the wire, the solder resist including an opening defined therethrough that exposes a portion of the wire,
wherein at least one of the first supporting bar and one or more of the plurality of first supporting ribs comprises substantially the same material as the wire.

17. The printed circuit board of claim 16, wherein the solder resist is formed on at least one of the first supporting bar and one or more of the plurality of first supporting ribs.

18. A printed circuit board comprising:
a base substrate having a top surface, a bottom surface opposite the top surface, a circuit region having an upper part, a lower part opposite the upper part, a left part between the upper and lower parts and a right part opposite the left part, and peripheral regions located around a periphery of the circuit region and including an upper peripheral region adjacent to the upper part, a lower peripheral region adjacent to the lower part, a left peripheral region adjacent to the left part and a right peripheral region adjacent to the right part, wherein a length of the upper peripheral region along the upper part is greater than a length of at least one of the left and right peripheral regions along the left and right parts;
a first supporting bar disposed on the top surface in the upper peripheral region and extending along the length of the upper peripheral region;
a plurality of first supporting ribs on the top surface within the upper peripheral region, wherein at least one of the plurality of first supporting ribs traverses the first supporting bar;
a second supporting bar disposed on the bottom surface in the upper peripheral region, wherein a location of the second supporting bar on the bottom surface in the upper peripheral region substantially corresponds to a location of the first supporting bar on the top surface in the upper peripheral region;
a plurality of second supporting ribs on the bottom surface within the upper peripheral region, wherein at least one of the plurality of second supporting ribs traverses the second supporting bar; and
an auxiliary supporting bar disposed on the base substrate in at least one of the left and right peripheral regions, wherein the auxiliary supporting bar is substantially parallel to at least one of the first and second supporting bars.

19. The printed circuit board of claim 18, wherein a length of the lower peripheral region along the lower part of the circuit region is greater than the length of at least one of the left and right peripheral regions along the left and right parts, the printed circuit board further comprising:
a plurality of first supporting bars and a plurality of second supporting bars,
wherein one of the plurality of first supporting bars is disposed on the top surface in the lower peripheral region, and
wherein one of the plurality of second supporting bars is disposed on the bottom surface in the lower peripheral region.

20. The printed circuit board of claim 18, wherein a width of at least one of the plurality of first supporting ribs is different from a width of at least one of the plurality of second supporting ribs.

21. The printed circuit board of claim 18, wherein a location of at least one of the plurality of second supporting ribs on the bottom surface substantially corresponds to a region between adjacent ones of the plurality of first supporting ribs on the top surface.

22. The printed circuit board of claim 18, further comprising:
a wire disposed on the circuit region; and
a solder resist disposed on the wire, the solder resist including an opening defined therethrough that exposes a portion of the wire,
wherein at least one of the first supporting bar and one or more of the plurality of first supporting ribs comprises substantially the same material as the wire.

23. The printed circuit board of claim 22, wherein the solder resist is disposed on at least one of the first supporting bar and one or more of the plurality of first supporting ribs.
